(19) United States
(12) Patent Application Publication
(10) Pub. No.: US 2009/0166770 A1
(43) Pub. Date: Jul. 2, 2009

(54) METHOD OF FABRICATING GATE ELECTRODE FOR GATE OF MOSFET AND STRUCTURE THEREOF

(75) Inventors: Oleg Gluschenkov, Poughkeepsie, NY (US); Sameer H. Jain, Beacon, NY (US); Yaocheng Liu, White Plains, NY (US)

Correspondence Address: HOFFMAN WARNICK LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 11/968,396

(22) Filed: Jan. 2, 2008

(51) Int. Cl. H01L 29/423; H01L 21/28

(52) U.S. Cl. 257/412; 438/592; 257/E29.128; 257/E21.177

(57) ABSTRACT

A method of fabricating a gate electrode for a gate of a metal oxide semiconductor field effect transistor (MOSFET), where the transistor has a structure incorporating a gate disposed on a substrate. The substrate comprises a source-drain region. The gate includes a gate electrode disposed on a gate dielectric and surrounded by a spacer. The gate electrode includes a capping layer of polysilicon (poly-Si) and a thin polycrystalline intermixed silicon-germanium (SiGe) layer superposed on the gate dielectric. The thin polycrystalline intermixed silicon-germanium (SiGe) layer may be formed by a high-temperature ultrafast melt-crystalization annealing process. The melt-crystallization process of the intermixed silicon-germanium provides an active dopant concentration that reduces the width of a depletion region formed at an interface of the polycrystalline intermixed silicon-germanium (SiGe) layer and the gate dielectric.

### BACKGROUND

1. Technical Field

The disclosure relates to gate patterning in metal oxide semiconductor field effect transistor (MOSFET) fabrication and the structure thereof. More particularly, the disclosure relates to fabrication of a gate electrode for a gate in a MOSFET using a melt-crystallization annealing process.

2. Related Art

In the current state of the art, crystalline polysilicon (poly-Si) is typically used as gate material in complimentary metal oxide semiconductor (CMOS). Continued scaling in CMOS devices leads to increased polysilicon depletion effects, which reduces gate capacitance and inversion charge density for a given gate bias. Polysilicon depletion effects maybe minimized by reducing the width of a depletion region, formed at an interface between polysilicon and gate oxide. The width of the depletion region is inversely proportional to active dopant concentration therein (i.e., increase in active dopant concentration in the depletion region reduces the width of depletion region). A dopant concentration ranging from 1E20 atoms/cm³ to 2E20 atoms/cm³ is usually achieved in crystalline polysilicon. To increase active dopant concentration or doping activation level in the depletion region further, silicon germanium (SiGe) may be used in place of poylsilicon.

However, processing of SiGe as gate material is less understood than poly-Si. For example, formation of SiGe on a gate dielectric with currently known methods presents a difficulty. Furthermore, while the use of SiGe as gate material leads to enhanced p-type MOSFET (PFET) performance, n-type doping activation level in poly-SiGe is believed to be lower than n-type doping activation attained in poly-Si. Comparatively, the performance of n-type MOSFET (NFET) with SiGe/poly-SiGe as gate material is degraded as to performance of NFET with poly-Si as gate material. This leads to a compromised performance of a device incorporating an NFET with a PFET.

In addition, the use of germanium (Ge) or SiGe as the gate material for the fabrication of a PFET tends to cause dopants, for example, boron (B) or indium(In) to diffuse, slowly, in the gate. This potentially reduces the active boron concentration at the gate-to-gate oxide interface. Therefore, the use of SiGe as gate material, with boron as dopant, limits any enhancement in the performance of such a MOSFET.

### SUMMARY

A method of fabricating a gate electrode for a gate of a metal oxide semiconductor field effect transistor (MOSFET), where the transistor has a structure incorporating a gate disposed on a substrate. The substrate comprises a source-drain region. The gate includes a gate electrode disposed on a gate dielectric and surrounded by a spacer. The gate electrode includes a capping layer of polysilicon (poly-Si) and a thin polycrystalline intermixed silicon-germanium (SiGe) layer superposed on the gate dielectric. The thin polycrystalline intermixed silicon-germanium (SiGe) layer may be formed by a high-temperature ultrafast melt-crystalization annealing process. The melt-crystallization process of the intermixed silicon-germanium provides an active dopant concentration that reduces the width of a depletion region formed at an interface of the polycrystalline intermixed silicon-germanium (SiGe) layer and the gate dielectric.

A first aspect of the invention provides a gate electrode for a gate of a metal oxide semiconductor field effect transistor (MOSFET), the gate electrode comprising: a silicon germanium (Si—Ge) layer disposed on a gate dielectric; and a silicon (Si) layer disposed on the Si—Ge layer, wherein the Si—Ge layer includes a polycrystalline intermix of silicon (Si) and germanium (Ge), and wherein the Si—Ge layer has a substantially uniform doping profile.

A second aspect of the invention provides a method of fabricating a gate electrode for a gate of a metal oxide semiconductor field effect transistor (MOSFET), the method comprising: depositing a thin silicon (Si) layer on a gate dielectric; depositing a silicon germanium (Si—Ge) layer on the thin Si layer, the silicon germanium layer comprising silicon (Si) and germanium (Ge) therein; implanting a dopant at a selected region of the Si—Ge layer with low energy; depositing a silicon capping layer on the Si—Ge layer; annealing the Si—Ge layer to intermix the Si and Ge therein with the thin Si layer to form an intermixed silicon-germanium (SiGe) layer directly above the gate dielectric; and subjecting the intermixed SiGe layer to a melt-crystallization process to form a polycrystalline intermixed SiGe layer having high doping activation.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 illustrates a cross-sectional view of an embodiment of a fabrication step for a gate electrode in a MOSFET of the disclosure.

FIG. 2 illustrates a cross-sectional view of another embodiment of a fabrication step for a gate electrode of a MOSFET of the disclosure.

FIG. 3 illustrates a cross-sectional view of an embodiment of an intermediate fabrication step for a gate electrode of a MOSFET.

FIG. 4 illustrates a cross-sectional view of an embodiment of a gate electrode of a MOSFET from the method of the disclosure.

The accompanying drawings are not to scale, and are incorporated to depict only typical aspects of the invention. Therefore, the drawings should not be construed in any manner that would be limiting to the scope of the invention. In the drawings, like numbering represents like elements between the drawings.

### DETAILED DESCRIPTION

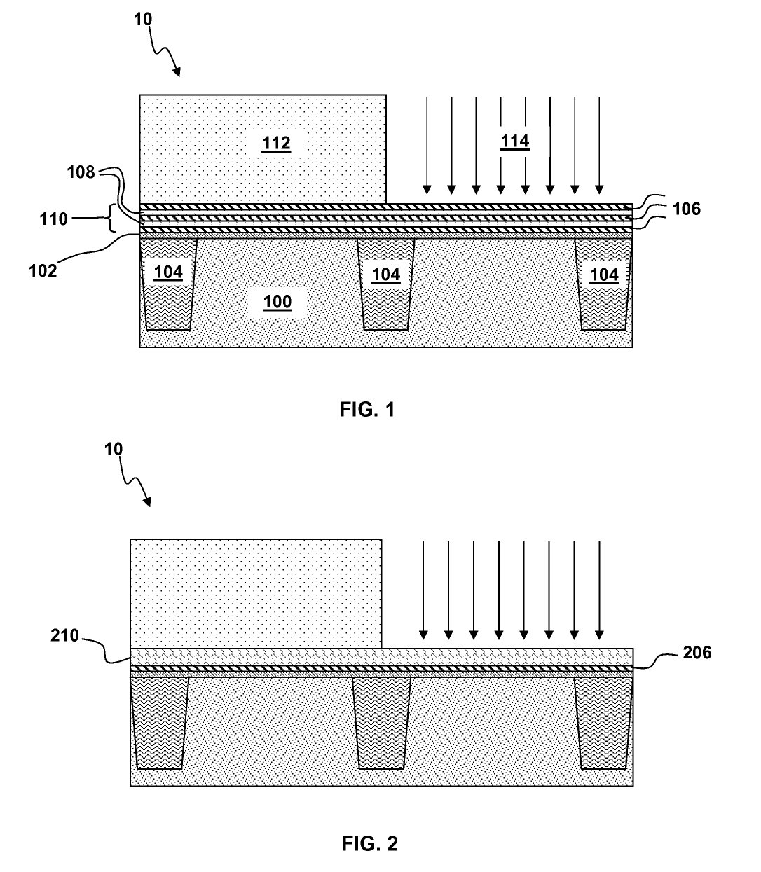

Embodiments depicted in the drawings in FIGS. 1-4 illustrate different aspects of fabricating a gate electrode for a gate of a metal oxide semiconductor field effect transistor (MOSFET) 10 which may comprise an n-type MOSFET (NFET) or a p-type MOSFET (PFET) or both.

FIG. 1 illustrates an exemplary embodiment, MOSFET 10, fabricated by currently known or later developed complementary metal oxide semiconductor (CMOS) processes where a gate dielectric layer 102 is disposed on a substrate 100. Substrate 100 may possibly include one or more conductive and/or insulating layers (not shown), and one or more active and/or passive devices/features, for example, shallow trench isolation (STI) region 104 to prevent diffusion of current from substrate 100. A silicon germanium (Si—Ge) layer 110, including alternating layers of silicon (Si) 106 and germanium (Ge) 108, is disposed on gate dielectric layer 102. Each of the alternating Si layers 106 and Ge layers 108 has a thickness ranging from approximately 1 nm to approximately 5 nm. The alternating Si layers 106 and Ge layers 108 may be arranged such that one of Si layer 106 forms a base layer disposed on gate dielectric layer 102 and one of Si layer 106 forms a top layer in Si—Ge layer 110. However, alternative embodiments (not shown) may have different multilayer structures comprising Si layers, SiGe layers and/or Ge layers. Having a thin Si layer 106 as a base layer facilitates the formation of SiGe in subsequent layers instead of depositing SiGe directly on gate dielectric layer 102. Having Si layer 106 as the top layer in the Si—Ge layer 110 facilitates wet cleaning and lithography processes. Each of the Si layers 106 may be amorphous silicon or polycrystalline silicon. Photoresist 112 may be applied for facilitating implantation 114 of dopants at a selected region of Si—Ge layer 110. The dopants may include, for example, but not limited to, boron (B) or indium (In) for fabricating a PFET. Low energy is used for implantation to achieve a high concentration of dopants at top surface of Si—Ge layer 110. Low energy, for example, at approximately 1 KeV, with high doses of boron fluorine (BF₂) ranging from approximately 1E15 atoms/cm² to approximately 3E15 atoms/cm² may be used for incorporating the dopants for a PFET. Similarly, arsenic (As), antimony (Sb), phosphorous (P) or any combination thereof may be used as dopants for fabricating an NFET.

FIG. 2 illustrates an alternative embodiment of the fabrication process for MOSFET 10. Instead of a Si—Ge layer 110 including of multiple alternating layers of Si layer 106 and Ge layers 108 (FIG. 1), a single amorphous silicon-germanium (Si—Ge) or polycrystalline silicon-germanium (poly Si—Ge) layer 210 is disposed on single amorphous Si layer 206. Amorphous or poly Si—Ge layer 210 may include approximately 20% to approximately 80% of germanium with a thickness of approximately 5 nm to approximately 10 nm. Single amorphous Si layer 206 may have a thickness ranging from approximately 1 nm to approximately 5 nm. Single amorphous Si layer 206 serves as a base layer for the deposition of amorphous or polysilicon Si—Ge layer 210 on gate dielectric layer 102 (FIG. 1). A cleaning step (not shown) using hydrogen fluoride (HF) may be applied to top surface of Si—Ge layer 110 (FIG. 1) or 210 (FIG. 2) to remove any native oxide.

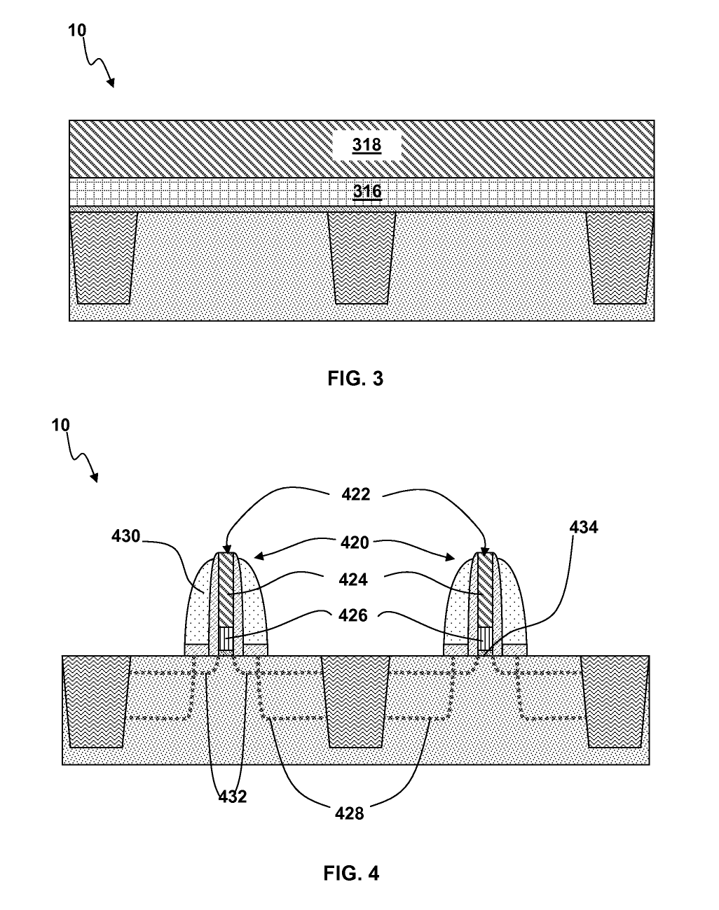

Following the cleaning step, a Si capping layer 318, illustrated in FIG. 3, is formed. Si capping layer 318 is formed from amorphous silicon or polysilicon. Intermixed SiGe layer 316 is formed through annealing of silicon germanium (Si—Ge) layer 110 (FIG. 1) or poly Si—Ge layer 210 and the amorphous Si layer 206 (FIG. 2) after deposition of Si capping layer 318. The annealing (not shown) is applied at approximately 500° C. to approximately 1000° C. for a duration ranging from approximately 1 second to approximately 60 minutes. The duration is dependent on the temperature selected. The annealing causes the silicon and germanium in the Si—Ge layers 110 (FIG. 1) or polysilicon-germanium in poly Si—Ge layer 210 and amorphous Si layer 206 (FIG. 2) to intermix to form intermixed SiGe layer 316 immediately on gate dielectric layer 102 (FIG. 1). Intermixed SiGe layer 316 may have a thickness of approximately 10 nm to approximately 20 nm. Si capping layer 318 may have a thickness ranging from approximately 40 nm to approximately 90 nm, which is crystallized following the annealing. The thickness of Si capping layer 318 is usually greater than the thickness of SiGe layer 316 and may vary with the thickness of SiGe layer 316 such that the combined thickness meets a target thickness ranging from approximately 60 nm to approximately 100 nm.

FIG. 4 illustrates MOSFET 10 including a gate 420 formed using currently known or later developed CMOS processes after the foregoing annealing step. Gate 420 is disposed on substrate 100 above extension-halo regions 432 and source-drain regions 428. Gate 420 may include spacers 430 that surround gate dielectric 434 and gate electrode 422. Gate electrode 422 may include crystallized polysilicon (poly-Si) layer 424 and polycrystalline intermixed SiGe layer 426. Poly-Si layer 424 is disposed on polycrystalline intermixed SiGe layer 426, which is formed by a melt-crystallization process of intermixed SiGe layer 316 (FIG. 3) following formation of gate 420. In the melt-crystallization process, intermixed SiGe layer 316 (FIG. 3) is melted with any one of currently known or later developed high-temperature ultrafast annealing techniques which does not melt poly-crystalline Si layer 424 or substrate 100. Examples of such annealing techniques may include, but not limited to, millisecond laser anneal, flash anneal and nanosecond laser anneal. On melting, intermixed SiGe layer 316 (FIG. 3) forms a thin molten SiGe layer (not shown) confined within gate 420. As the melting point of the intermixed silicon-germanium is much lower than the melting point of polysilicon, crystallized poly-Si layer 424 does not melt in the melt-crystallization process of the high-temperature ultrafast annealing step. Integrity of gate 420 is maintained by crystallized poly-Si layer 424 in the gate electrode 422 being resistant to melting. On cooling, melted SiGe crystallizes to form a polycrystalline intermixed SiGe layer 426 with a thickness ranging from approximately 5 nm to approximately 20 nm. Melted-crystallized polycrystalline intermixed SiGe layer 426 includes a uniform doping profile with active dopant concentrations of approximately 3E20 atoms/cm³ to approximately 6E20 atoms/cm³, preferably approximately 5E20 atoms/cm³, which results in a reduced width of depletion.

The foregoing description of various aspects of the invention has been presented for purposes of illustration and description. It is not intended to be exhaustive or to limit the scope of the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A gate electrode for a gate of a metal oxide semiconductor field effect transistor (MOSFET), the gate electrode comprising:
a silicon germanium (Si—Ge) layer disposed on a gate dielectric; and
a silicon (Si) layer disposed on the Si—Ge layer,
wherein the Si—Ge layer includes a polycrystalline intermix of silicon (Si) and germanium (Ge), and
wherein the Si—Ge layer has a substantially uniform doping profile.

2. The gate electrode of claim 1, wherein the poly-Si layer includes a thickness greater than a thickness of the Si—Ge layer.

3. The gate electrode of claim 1, wherein the Si layer includes one of amorphous silicon and polycrystalline silicon.

4. The gate electrode of claim 1, wherein the Si—Ge layer includes approximately 20% to approximately 80% germanium (Ge).

5. The gate electrode of claim 1, wherein the Si—Ge layer is doped with one of a group consisting of: boron (B), indium (In), arsenic (As), antimony (Sb), phosphorous (P) and any combination thereof.

6. The gate electrode of claim 5, wherein the substantially uniform doping profile has approximately 3E20 atoms/cm³ to approximately 6E20 atoms/cm³.

7. A method of fabricating a gate electrode for a gate of a metal oxide semiconductor field effect transistor (MOSFET), the method comprising:
depositing a thin silicon (Si) layer on a gate dielectric;
depositing a silicon germanium (Si—Ge) layer on the thin Si layer, the silicon germanium layer comprising silicon (Si) and germanium (Ge) therein;
implanting a dopant at a selected region of the Si—Ge layer with low energy;
depositing a silicon capping layer on the Si—Ge layer;
annealing the Si—Ge layer to intermix the Si and Ge therein with the thin Si layer to form an intermixed silicon-germanium (SiGe) layer directly above the gate dielectric; and
subjecting the intermixed SiGe layer to a melt-crystallization process to form a polycrystalline intermixed SiGe layer having high doping activation.

8. The method of claim 7, wherein the Si—Ge layer comprises multiple Si layers and multiple Ge layers, each of the multiple Si layers alternating with each of the multiple Ge layers.

9. The method of claim 8, wherein each of the multiple Si layers and each of the multiple Ge layers has a thickness ranging from approximately 1 nm to approximately 5 nm.

10. The method of claim 7, wherein the Si—Ge layer is selected from a group consisting of: amorphous silicon-germanium, polycrystalline silicon-germanium and a combination thereof.

11. The method of claim 7, wherein the dopant is selected from a group consisting of: boron (B), indium (In), arsenic (As), antimony (Sb), phosphorous (P) and any combination thereof.

12. The method of claim 7, wherein the Si layer is selected from a group consisting of: amorphous silicon and polycrystalline silicon.

13. The method of claim 7, wherein the melt-crystallization process is performed with one of a group consisting of: millisecond laser anneal, flash anneal and nanosecond laser anneal.
